(19) United States
(12) Patent Application Publication
(10) Pub. No.: US 2026/0118914 A1
(43) Pub. Date: Apr. 30, 2026

(54) DISPLAY PANEL AND DISPLAY APPARATUS

(71) Applicant: Xiamen Tianma Display Technology Co., Ltd., Xiamen (CN)

(72) Inventors: Wenshuo LIN, Xiamen (CN); Huomei HUA, Xiamen (CN); Wenzhi LI, Xiamen (CN)

(73) Assignee: Xiamen Tianma Display Technology Co., Ltd., Xiamen (CN)

(21) Appl. No.: 19/183,969

(22) Filed: Apr. 21, 2025

(30) Foreign Application Priority Data
Oct. 31, 2024 (CN) 202411545061.6

(51) Int. Cl. H10K 59/122; G06F 3/041; G06F 3/044; H10K 59/40

(52) U.S. Cl. CPC H10K 59/122; G06F 3/0412; G06F 3/0446; H10K 59/40; G06F 2203/04107

(57) ABSTRACT

The present application relates to a display panel and a display apparatus. The display panel includes a first area, a second area around the first area, a substrate, a display light-emitting layer, and a touch layer. The display light-emitting layer is on the substrate and includes a plurality of support structures each including a first sub-support structure and a second sub-support structure, and a dimension of the first sub-support structure along a thickness direction of the display panel is greater than that of the second sub-support structure along the thickness direction of the display panel. The touch layer includes touch electrodes in the first area and a plurality of touch traces in the second area electrically connected to the touch electrodes. Orthographic projections of at least a part of the plurality of touch traces on the substrate do not overlap with that of the first sub-support structures on the substrate.

### CROSS-REFERENCE TO RELATED APPLICATION

The present application claims priority to Chinese Patent Application No 202411545061.6 entitled “DISPLAY PANEL AND DISPLAY APPARATUS” filed on Oct. 31, 2024, which is incorporated herein by reference in its entirety.

### TECHNICAL FIELD

The present application relates to the field of display technology, and particularly, to a display panel and a display apparatus.

### BACKGROUND

With the continuous development of display technology, consumers'demands for display panels are constantly increasing, and various display panels, such as liquid crystal display panels, and organic light-emitting display panels, have emerged one after another, and have been developed rapidly. On this basis, display technologies, such as 3D display, touch display technology, curved display, ultra-high resolution display, and peep-proof display, are constantly emerging to meet needs of the consumers. A touch function is basically one of necessary functions of current display screens, and there are various forms and structures, such as self-capacitance, mutual-capacitance and other touch modes, and built-in, external, or external touch structures, for achieving the touch functions.

However, due to a limitation of an existing manufacturing process and a structure of the display panel, a manufacturing yield of the display panel cannot meet the demands.

### SUMMARY

A display panel and a display apparatus according to embodiments of the present application can effectively improve a manufacturing yield of the display panel.

In an aspect, a display panel is provided according to embodiments of the present application, the display panel includes a first area and a second area provided around the first area, and the display panel further includes a substrate, a display light-emitting layer, and a touch layer. The display light-emitting layer is provided on the substrate and includes a plurality of support structures each including a first sub-support structure and a second sub-support structure, and a dimension of the first sub-support structure along a thickness direction of the display panel is greater than a dimension of the second sub-support structure along the thickness direction of the display panel. The touch layer includes touch electrodes and a plurality of touch traces, the touch traces are electrically connected to the touch electrodes, the touch electrodes are located in the first area, and the touch traces are located in the second area. Orthographic projections of at least a part of the plurality of touch traces on the substrate do not overlap with orthographic projections of the first sub-support structures on the substrate.

In another aspect, embodiments of the present application further provide a display apparatus including the above display panel.

### BRIEF DESCRIPTION OF THE DRAWINGS

Features, advantages, and technical effects of exemplary embodiments of the present application will be described below with reference to the accompanying drawings.

FIG. 1 is a schematic structural view of a display panel according to some embodiments of the present application;

FIG. 2 is a schematic structural view of another display panel according to some embodiments of the present application;

FIG. 3 is a sectional schematic structural view of a display panel according to some embodiments of the present application;

FIG. 4 is a partial schematic structural view of Q in FIG. 3;

FIG. 5 is a partial schematic structural view of P in FIG. 2;

FIG. 6 is another partial schematic structural view of P in FIG. 2;

FIG. 7 is yet another partial schematic structural view of P in FIG. 2;

FIG. 8 is yet another partial schematic structural view of P in FIG. 2;

FIG. 9 is a schematic structural view of yet another display panel according to some embodiments of the present application;

FIG. 10 is a partial schematic structural view of R in FIG. 9;

FIG. 11 is a sectional schematic structural view of another display panel according to some embodiments of the present application;

FIG. 12 is another partial schematic structural view of P in FIG. 2;

FIG. 13 is yet another partial schematic structural view of P in FIG. 2;

FIG. 14 is yet another partial schematic structural view of P in FIG. 2;

FIG. 15 is yet another partial schematic structural view of P in FIG. 2;

FIG. 16 is a schematic structural view of yet another display panel according to some embodiments of the present application;

FIG. 17 is a schematic structural view of yet another display panel according to some embodiments of the present application;

FIG. 18 is a schematic structural view of yet another display panel according to some embodiments of the present application;

FIG. 19 is a sectional schematic structural view of yet another display panel according to some embodiments of the present application; and

FIG. 20 is a schematic structural view of a display apparatus according to some embodiments of the present application.

### REFERENCE SIGNS

100: Display panel; 200: Display apparatus;
A1: First area; A2: Second area; A21: Binding area;
MK: Mask area; MK1: Corner area;
10: Substrate; 20: Display light-emitting layer; 21: Support structure; 211: First sub-support structure; 212: Second sub-support structure; 22: Light-emitting layer; 30: Encapsulation layer;
40: Touch layer; 41: Touch electrode; 411: First touch electrode; 412: Second touch electrode; 42: touch trace; 421: First segment; 422: Second segment; 423: Third segment; 424: Connection segment; 4241: First sub-connection segment; 4242: Second sub-connection segment; 425: First touch trace; 426: Second touch trace; 43: Virtual touch trace; 44: Shielding line;
50: Light-filtering layer; 51: Light-filtering unit; 52: Light-shielding portion;
L1: First set of touch traces; L11: 1st first touch trace; L12: M-th first touch trace; L2: Second set of touch traces; L21: (M+1)-th first touch trace; L22: N-th first touch trace;
M1: First conductive layer; M11: First conductive portion; M2: Second conductive layer; M21: Second conductive portion; IC: Control chip; X: First direction; Y: Second direction; and Z: thickness direction.

In the accompanying drawings, the same reference numerals represent the same components. The accompanying drawings are not drawn to actual scale.

### DETAILED DESCRIPTION

Features and exemplary embodiments of various aspects of the present application will be described in detail below. In order to make the objects, technical solutions and advantages of the present application clearer, the present application is further described in detail below with reference to the accompanying drawings and specific embodiments. It should be understood that the specific embodiments described herein are merely intended to explain the present application, rather than to limit the present application. For those skilled in the art, the present application can be implemented without some of these specific details. The following description of the embodiments is only to provide a better understanding of the present application by illustrating examples of the present application.

It should be noted that, in the present disclosure, the relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device including a series of elements includes not only those elements, but also other elements that are not explicitly listed or elements inherent to such a process, method, article or device. Without more constraints, the elements following an expression “comprise/include.” do not exclude the existence of additional identical elements in the process, method, article or device that includes the elements.

It should be understood the term “and/or” used herein refers to only an association relationship for describing associated objects, and means that there may be three kinds of relationships. For example, “A and/or B” may represent three cases including: “A exists alone”, “A and B exist simultaneously”, and “B exists alone”. In addition, the character “/” herein generally indicates that the associated objects have an “or” relationship.

A display panel includes a display light-emitting layer including a light-emitting layer and support structures provided on a substrate, and before manufacturing of the light-emitting layer, a mask plate covers the substrate and is supported by the support structures. In a manufacturing process of the light-emitting layer, some materials of the light-emitting layer will adhere to the mask plate, and having accumulated to a certain amount, the materials of the light-emitting layer will fall onto the support structures, resulting in an increase in an overall height of the support structures. After the light-emitting layer is manufactured, it is usually necessary to manufacture an encapsulation layer. Since the overall height of the support structures changes, the manufactured encapsulation layer becomes uneven. Touch traces are provided on the encapsulation layer and will be burst or even disconnected by protruding structures at positions where the support structures are located, resulting in a reduction in a manufacturing yield since the touch traces cannot normally transmit touch signals.

In view of the above problem, embodiments of the present application provide a display panel in a first aspect.

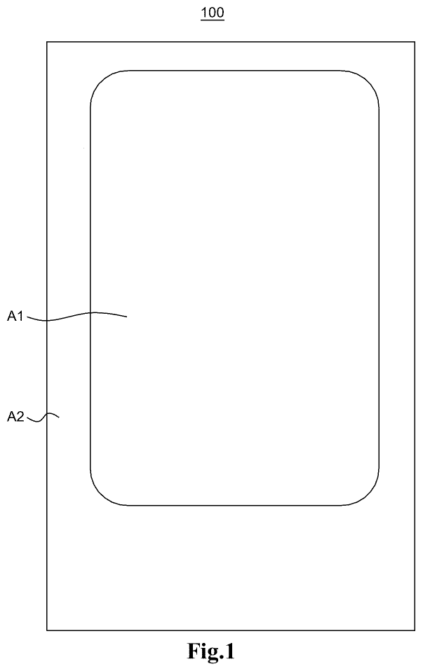

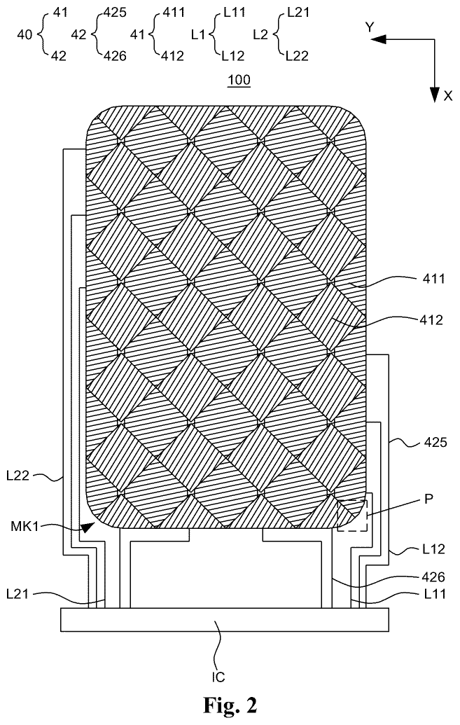

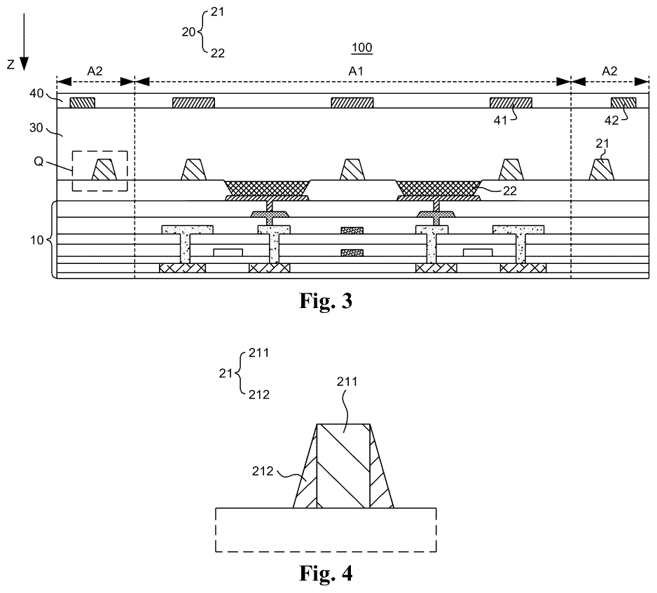

FIG. 1 shows a schematic structural view of a display panel according to some embodiments of the present application. FIG. 2 is a schematic structural view of another display panel according to some embodiments of the present application. FIG. 3 is a sectional schematic structural view of a display panel according to some embodiments of the present application. FIG. 4 is a partial schematic structural view of Q in FIG. 3.

As shown in FIG. 1 to FIG. 4, the embodiments of the present application provide a display panel 100. The display panel 100 includes a first area Al and a second area A2 provided around the first area A1; the he display panel 100 further includes a substrate 10, a display light-emitting layer 20, and a touch layer 40. The display light-emitting layer 20 is provided on the substrate 10 and includes a plurality of support structures 21 each including a first sub-support structure 211 and a second sub-support structure 212, and a dimension of the first sub-support structure 211 along a thickness direction Z of the display panel 100 is greater than a dimension of the second sub-support structure 212 along the thickness direction Z of the display panel 100. The touch layer 40 includes touch electrodes 41 and a plurality of touch traces 42, the touch traces 42 are electrically connected to the touch electrodes 41, the touch electrodes 41 are located in the first area A1, and the touch traces 42 are located in the second area A2. Orthographic projections of at least a part of the plurality of touch traces 42 on the substrate 10 do not overlap with orthographic projections of the first sub-support structures 211 on the substrate 10.

In some examples, the first area Al may be a display area, and the second area A2 may be a non-display area. In an example, the first area Al may be used for a display function of the display panel 100. The second area A2 may be used for providing structures such as a photosensitive device, a metal trace, and a frame therein.

In some other examples, the first area Al may be a touch area, and the second area A2 may be a non-touch area. Optionally, the touch area may include the display area or part of the non-display area. An example in which the first area Al is the touch area and the second area A2 is the non-touch area is given for illustration below.

The substrate 10 mainly plays supporting and bearing roles, other film layers are stacked in sequence on the substrate 10, and the “stacked” mentioned herein means that other film layers are stacked in sequence along a thickness direction Z of the substrate 10. The substrate 10 may include a single or a plurality of film layer structures, and specific film layer structures of the substrate 10 are not limited in the embodiments of the present application. In addition, thickness directions Z of other film layers located on a side of the substrate 10 are generally the same as the thickness direction Z of the substrate 10, therefore, for the convenience of description, the thickness direction Z of the substrate 10 or the thickness directions Z of other film layers mentioned below in the embodiments of the present application is shown as the same direction. The substrate 10 may be a rigid substrate 10 such as a glass substrate 10. Alternatively, the substrate 10 may be a flexible substrate 10, and may include, for example, an organic material such as polyimide.

The display light-emitting layer 20 may include a light-emitting layer 22. In an example, the light-emitting layer 22 is located on the substrate 10, along a direction parallel to a plane where the substrate 10 is located, and the light-emitting layer 22 includes a plurality of light-emitting units which are main devices for achieving light-emitting and display. The light-emitting layer 22 of the light-emitting unit may include a light-emitting functional layer. Alternatively, the light-emitting layer 22 may include at least one of a hole inject layer (HIL), a hole transport layer (HTL), an electron blocking layer, a hole blocking layer, an electron inject layer (EIL), and an electron transport layer (ETL) which are provided in a stack.

The display light-emitting layer 20 includes the support structures 21 that may be provided on the substrate 10. Alternatively, the display light-emitting layer 20 may further include a pixel definition layer including pixel definition portions and pixel openings, the light-emitting layer 22 is provided in the pixel opening, the pixel definition portion encloses the pixel opening, and the support structures 21 may be provided on sides of the pixel definition portions away from the substrate 10.

The first sub-support structures 211 are used for supporting the mask plate to carry out manufacturing of the light-emitting film layer in the display panel 100. For example, the mask plate is a rectangle in shape, and the first sub-support structures 211 support four corners of the mask plate.

Optionally, the first sub-support structures 211 may be spaced apart from the second sub-support structures 212. Alternatively, the second sub-support structure 212 is provided on a periphery of the first sub-support structure 211. Alternatively, the first sub-support structure 211 is provided on a periphery of the second sub-support structure 212.

In an example, under a condition that the second sub-support structure 212 is provided on the periphery of the first sub-support structure 211, in a manufacturing process of the light-emitting film layer, when a part of light-emitting materials drop on the first sub-support structures 211 along the mask plate, the part of the light-emitting materials may slide along sidewalls of the second sub-support structures 212, thereby reducing the possibility that dimensions of the first sub-support structures 211 along the thickness direction are increased due to dropping of the light-emitting materials on the first sub-support structures 211.

In an example, under a condition that the first sub-support structures 211 may be spaced apart from the second sub-support structures 212, in the manufacturing process of the light-emitting film layer, when the mask plate are deformed due to the adhesion of the light-emitting materials to the mask plate, since the second sub-support structures 212 may support the mask plate, a possibility of abnormality in a position or even a color mixing of the light-emitting film layer due to deformation of mask openings caused by the deformation of the mask plate is reduced.

The touch layer 40 includes the touch electrodes 41 and the touch traces 42, and optionally, the touch electrodes 41 may achieve touch functions by self-capacitance and/or mutual-capacitance. In an example, the touch electrode 41 includes a transmission electrode and a sensing electrode that are connected to different touch traces 42.

The touch electrodes 41 are located in the first area A1, so that the first area A1 forms the touch area, and under a condition that users'fingertips or any conductive objects contact the first area A1 of screens, accurate coordinate signals can be immediately triggered, locating contact positions accurately to achieve interactions with the users.

The touch traces 42 are located in the second area A2 and may extend adaptively to the shape of the second area A2. For example, the second area A2 is a rectangle in shape, and the touch traces 42 extend along extension directions of edges of the rectangle. Alternatively, the second area A2 is a circle in shape, and the touch traces 42 extend along an arc.

In some embodiments, orthographic projections of the plurality of touch traces 42 on the substrate 10 do not overlap with the orthographic projections of the first sub-support structures 211 on the substrate 10. In some other embodiments, orthographic projections of a part of the plurality of touch traces 42 on the substrate 10 do not overlap with the orthographic projections of the first sub-support structures 211 on the substrate 10. “Not overlap” herein may mean that the orthographic projections of the touch traces 42 on the substrate 10 are spaced apart from the orthographic projections of the first sub-support structures 211 on the substrate 10, or the orthographic projections of the touch trace 42 on the substrate 10 are tangent to edges of the orthographic projections of the first sub-support structures 211 on the substrate 10. Optionally, the first sub-support structures 211 and the second sub-support structures 212 are all provided in the second area A2; alternatively, neither the first sub-support structures 211 nor the second sub-support structures 212 are provided in the second area A2; alternatively, the first sub-support structures 211 are not provided in the second area A2, and the second sub-support structures 212 are provided in the second area A2; alternatively, the first sub-support structures 211 are provided in the second area A2, and the second sub-support structures 212 are not provided in the second area A2. Under a condition that the first sub-support structures 211 are not provided in the second area A2, the first sub-support structures 211 may be provided in the first area A1. Under a condition that the second sub-support structures 212 are not provided in the second area A2, the second sub-support structures 212 may be provided in the first area A1.

In some embodiments, the orthographic projections of the plurality of touch traces 42 on the substrate 10 do not overlap with orthographic projections of the second sub-support structures 212 on the substrate 10. In some other embodiments, at least parts of the orthographic projections of the plurality of touch traces 42 on the substrate 10 overlap with the orthographic projections of the second sub-support structures 212 on the substrate 10.

In the display panel 100 according to the present application, the support structures 21 may support the mask plate to carry out the manufacturing of the light-emitting film layer in the display panel 100, and the touch traces 42 are used for achieving signal transmissions of the touch electrodes 41. When the light-emitting film layer is manufactured, some light-emitting materials will drop on the first sub-support structures and the second sub-support structures along the mask plate, and a dimension of the first sub-support structure along the thickness direction and a dimension of the second sub-support structure along the thickness direction will increase with accumulation of light-emitting materials on the first sub-support structures and the second sub-support structures. Since the dimension of the first sub-support structure 211 along the thickness direction Z is greater than the dimension of the second sub-support structure 212 along the thickness direction Z, a film layer over an area where the first sub-support structure 211 is located protrudes from a film layer over an area where the second sub-support structure 212 is located with respect to a plane parallel to the display panel, and the touch traces avoid uneven areas of the film layers under the touch traces by not overlapping the orthographic projections of the touch traces 42 on the substrate 10 with the orthographic projections of the first sub-support structures 211 on the substrate 10, thereby reducing a risk of cracking or even disconnection of the touch traces 42 due to an unevenness of a film layer under the touch layer 40 (the film layer over the support structure 21), and improving the manufacturing yield of the display panel.

In some embodiments, an encapsulation layer 30 is provided between the display light-emitting layer 20 and the touch layer 40. For example, the encapsulation layer 30 includes a first encapsulation layer, a second encapsulation layer, and a third encapsulation layer. The first encapsulation layer, the second encapsulation layer, and the third encapsulation layer may be provided together between the support structure 21 and the touch layer 40. Of course, one or any combination of the first encapsulation layer, the second encapsulation layer, and the third encapsulation layer may be provided between the support structure 21 and the touch layer 40.

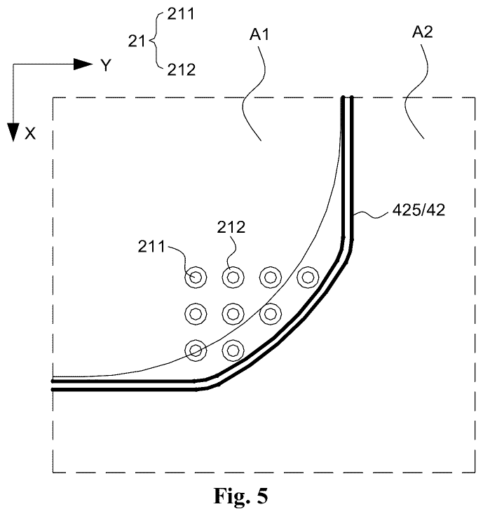

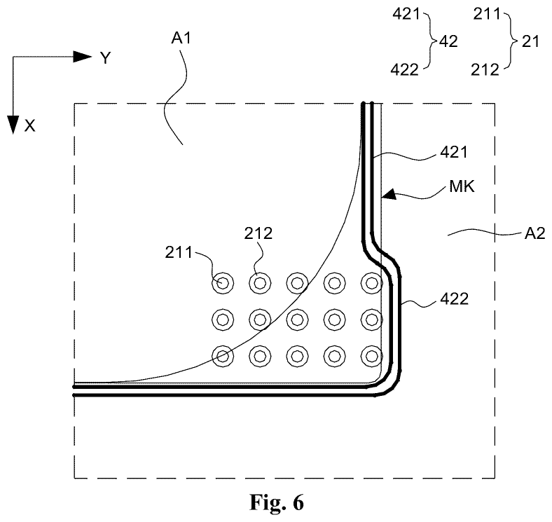

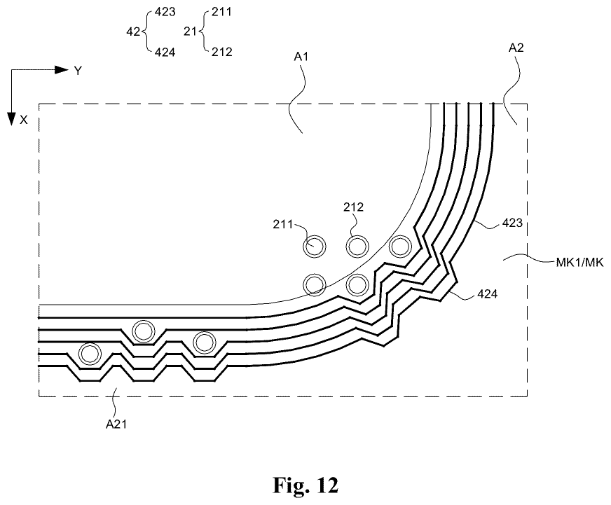

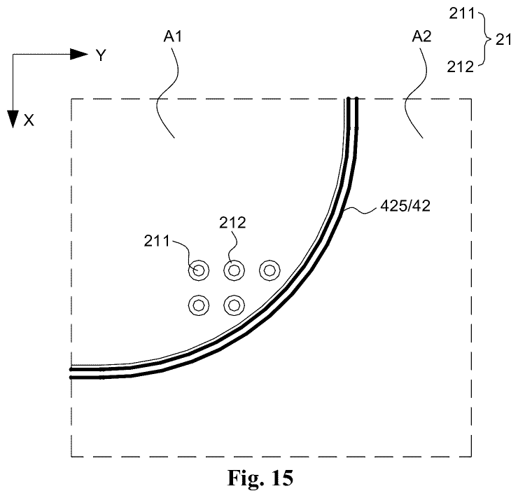

FIG. 5 is a partial schematic structural view of P in FIG. 2. Thick solid lines in FIG. 5, FIG. 6 to FIG. 10, FIG. 12, and FIG. 15 below are only for distinguishing structures therein from other structures, and are not for indicating a difference in radial dimensions of the structures.

As shown in FIG. 2 to FIG. 5, in some optional embodiments, at least a part of first sub-support structures 211 and/or second sub-support structures 212 are provided in the second area A2.

In some embodiments, a plurality of first sub-support structures 211 are all provided in the second area A2. In some other embodiments, a part of the plurality of first sub-support structures 211 are provided in the second area A2, and another part are provided in the first area A1 and/or the second area A2.

In some embodiments, a plurality of second sub-support structures 212 are all provided in the second area A2. In some other embodiments, a part of the plurality of second sub-support structures 212 are provided in the second area A2, and another part are provided in the first area A1 and/or the second area A2.

In some embodiments, the plurality of first sub-support structures 211 and the plurality of second sub-support structures 212 are all provided in the second area A2. In some other embodiments, a part of the plurality of first sub-support structures 211 are provided in the second area A2, another part of the plurality of first sub-support structures 211 are provided in the first area A1, and a part of the plurality of second sub-support structures 212 are provided in the second area A2, and another part of the plurality of second sub-support structures 212 is provided in the first area A1.

In these optional embodiments, providing the first sub-support structures 211 and/or the second sub-support structures 212 in the second area A2 is beneficial to increase an area for supporting the mask plate, reducing the possibility of a decrease in a manufacturing yield of the light-emitting layer 22 since the mask plate deform to contact the film layer in the display panel 100.

As shown in FIG. 3 and FIG. 4, in some optional embodiments, the second sub-support structure 212 is provided around a periphery of the first sub-support structure 211, and the second sub-support structure 212 is connected to a sidewall of the first sub-support structure 211.

In an example, the first sub-support structure 211 and the second sub-support structure 212 together form a circular truncated cone or a cone.

In these optional embodiments, the first sub-support structures 211 may be used as structures that mainly support the mask plate, the second sub-support structures 212 may be used for dispersing the stress that the first sub-support structures 211 bear, and since the second sub-support structure 212 is connected to the sidewall of the first sub-support, overall stability and reliability of the support structure 21 are improved.

FIG. 6 is yet another partial schematic structural view of P in FIG. 2.

As shown in FIG. 2 to FIG. 6, in some optional embodiments, the second area A2 includes a first sub-area provided around the first area A1 and a second sub-area located at a side of the first sub-area away from the first area A1. The display panel 100 includes a mask area MK covering the first area A1 and the first sub-area, the mask area MK includes a corner area MK1 covering corners of the first area A1 and the first sub-area, and the first sub-support structures 211 and/or the second sub-support structures 212 are provided in the corner area MK1

Optionally, a shape of the first sub-area and a shape of the second sub-area match a shape of the first area A1. For example, the first area A1 is a rectangle in shape, and the first sub-area and the second sub-area are both rectangular rings in shape. For example, the first area A1 is a circle in shape, and the first sub-area and the second sub-area are both circular rings in shape.

Optionally, the second sub-area is provided around the first sub-area.

Optionally, the mask area MK may be an area for providing the mask plate in a process of manufacturing the light-emitting layer 22. The mask area MK further includes the corner area MK1, and the corner area MK1 covers corners of the first area A1 and corners of the first sub-area. A corner is often a place where a structure is fragile and easily damaged, and the first sub-support structures 211 are provided in the corners of the first sub-area, which is beneficial to enhance mechanical stability and durability of the corner area MK1 of the first sub-area.

In these optional embodiments, the above arrangements are beneficial to improve structural stability of the mask plate supported by the support structures 21, and reduce interference of the support structures 21 to the touch traces 42.

As shown in FIG. 5 and FIG. 6, in some optional embodiments, the orthographic projections of the first sub-support structures 211 and/or the second sub-support structures 212 on the substrate 10 do not overlap with the orthographic projections of the touch traces 42 on the substrate 10.

In an example, the orthographic projections of the first sub-support structures 211 on the substrate 10 do not overlap with the orthographic projections of the touch traces 42 on the substrate 10, for example, the orthographic projections of the first sub-support structures 211 on the substrate 10 are spaced apart from the orthographic projections of the touch traces 42 on the substrate 10; alternatively, the orthographic projections of the first sub-support structures 211 on the substrate 10 are tangent to edges the orthographic projections of the touch traces 42 on the substrate 10.

In an example, the orthographic projections of the second sub-support structures 212 on the substrate 10 do not overlap with the orthographic projections of the touch traces 42 on the substrate 10, for example, the orthographic projections of the second sub-support structures 212 on the substrate 10 are spaced apart from the orthographic projections of the touch traces 42 on the substrate 10; alternatively, the orthographic projections of the second sub-support structures 212 on the substrate 10 are tangent to edges of the orthographic projections of the touch traces 42 on the substrate 10.

In these optional embodiments, through the above arrangements, the touch traces 42 avoid an area under the film layer where the first sub-support structure 211 and/or the second sub-support structure 212 are provided, thereby reducing an effect on the touch traces 42 under a condition that the film layers over the first sub-support structures 211 and the second sub-support structures 212 have abnormal thickness uniformity, and improving a manufacturing yield of the touch traces 42.

As shown in FIG. 2, in some optional embodiments, the display panel 100 further includes a control chip IC located in the second area A2 on a side of the first area A1 along a first direction X, and the corner area MK1 is a corner located in the first area A1 close to the control chip IC along the first direction X.

Optionally, an example in which the second area A2 is a rectangular ring in shape is given, long side areas of the second area A2 are located on two sides of the first area A1 along a second direction Y, short side areas of the second area A2 are located on two sides of the first area A1 along the first direction X, the control chip IC is located in the short side areas of the second area A2, the corner area MK1 is a corner close to the control chip IC along the first direction X, and the support structures 21 are provided in the corner area MK1, which is beneficial to increase overall strength of the corner area MK1, reduce a possibility of damage to the control chip IC caused in the manufacturing process or under external force, and improve the reliability.

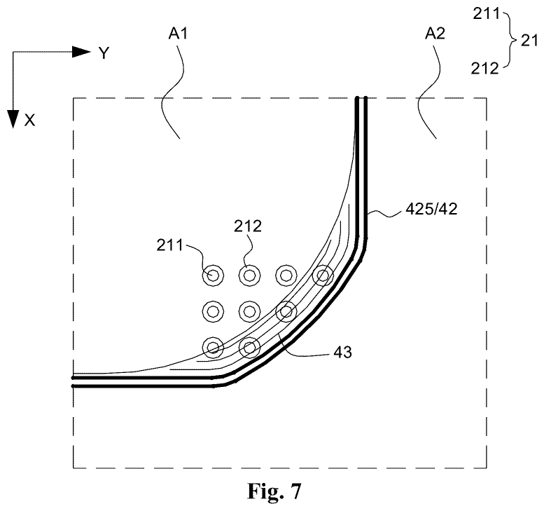

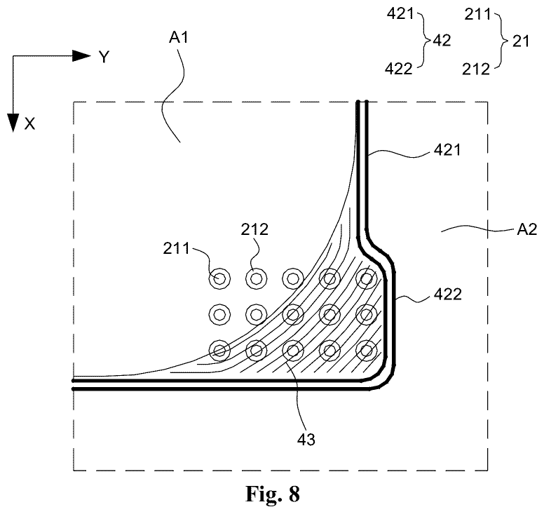

FIG. 7 is yet another partial schematic structural view of P in FIG. 2. FIG. 8 is yet another partial schematic structural view of P in FIG. 2.

As shown in FIG. 7 and FIG. 8, in some optional embodiments, the touch layer 40 further includes virtual touch traces 43 insulated from the touch traces, and the virtual touch traces 43 are provided in the corner area MK1.

The virtual touch traces 43 may not transmit the touch signals and may be used as shielding structures, so that a shielding area of an area where the touch traces 42 are located is the same as a shielding area of the virtual touch traces 43, improving uniformity of display effects of different areas of the display panel 100, and reducing a possibility of abnormality in display effects of the display panel 100.

Optionally, orthographic projections of the virtual touch traces 43 on the substrate 10 overlap with the orthographic projections of the first sub-support structures 211 on the substrate 10. Of course, the orthographic projections of the virtual touch traces 43 on the substrate 10 may not overlap with the orthographic projections of the first sub-support structures 211 on the substrate 10.

Optionally, the orthographic projections of the virtual touch traces 43 on the substrate 10 overlap with the orthographic projections of the second sub-support structures 212 on the substrate 10. Of course, the orthographic projections of the virtual touch traces 43 on the substrate 10 may not overlap with the orthographic projections of the second sub-support structures 212 on the substrate 10.

Optionally, extension directions of the virtual touch traces 43 may be the same as extension directions of the touch traces 42.

Optionally, the virtual touch traces 43 and the touch traces may be provided in the same layer, and of course, the virtual touch traces 43 and the touch traces may be provided in different layers.

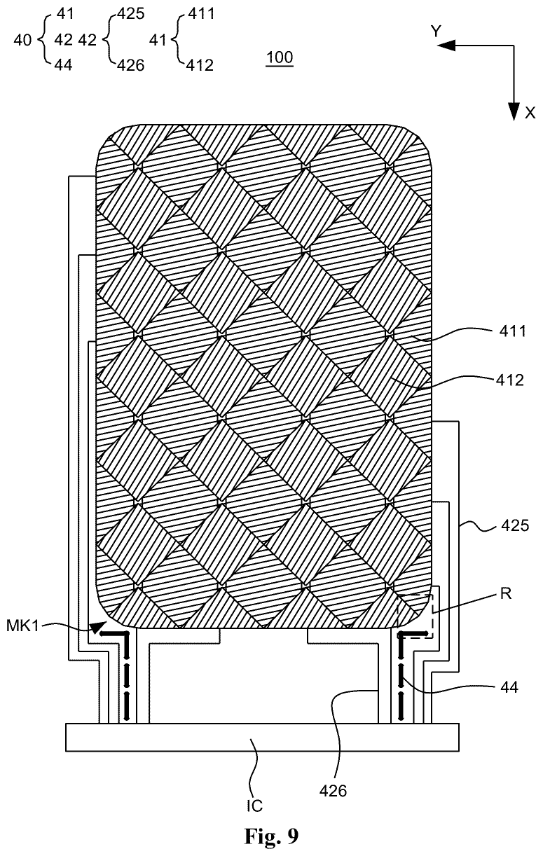

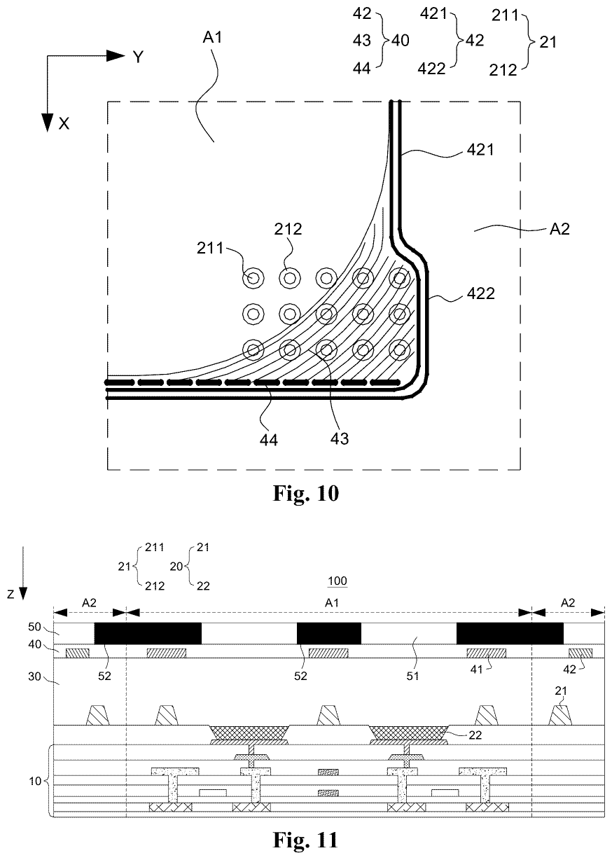

FIG. 9 is a schematic structural view of yet another display panel according to some embodiments of the present application. FIG. 10 is a partial schematic structural view of R in FIG. 9. Thick dashed lines in FIG. 9 and FIG. 10 are shielding lines, and the thick dashed lines in the drawings are only for distinguishing themselves from other traces and are not non-existent traces. Shielding traces are continuous traces, and are not the thick dashed lines shown in segments in FIG. 8 and FIG. 9.

As shown in FIG. 9 and FIG. 10, in some optional embodiments, the touch traces 42 include a first touch trace 425 and a second touch trace 426, the touch electrodes 41 include first touch electrode 411 and a second touch electrode 412 insulated from each other, the first touch trace 425 is electrically connected to the first touch electrode 411, the second touch trace 426 is electrically connected to the second touch electrode 412, and the touch layer 40 further includes shielding lines 44 each located between the first touch trace 425 and the second touch trace 426. At least a part of the virtual touch traces 43 are electrically connected to the shielding lines 44.

Optionally, one of the first touch electrode 411 and the second touch electrode 412 may be a transmission electrode, and the other may be a sensing electrode; one of the first touch trace 425 and the second touch trace 426 may be a touch trace 42 for transmitting a sensing signal, and the other may be a touch trace 42 for transmitting a transmission signal. The first touch traces 425 and the second touch traces 426 transmit different signals, and the shielding line 44 is located between the first touch trace 425 and the second touch trace 426, which may reduce a possibility of crosstalk between the signal in the first touch trace 425 and the signal in the second touch trace 426, and improve reliability of the touch function. Optionally, the shielding lines 44 and the touch traces may be provided in the same layer. The shielding line 44 is electrically connected to the virtual touch trace, and in other words, the shielding line 44 and the virtual touch trace may be reused with each other, that is, the same trace may be used as the shielding line 44 and the virtual touch trace.

FIG. 11 is a sectional schematic structural view of yet another display panel according to some embodiments of the present application.

As shown in FIG. 11, in some optional embodiments, the display panel 100 further includes a light-filtering layer 50 located on a side of the touch layer 40 away from the substrate 10, the light-filtering layer 50 includes light-filtering units 51 and light-shielding portions 52, and the light-shielding portion 52 is located between two adjacent light-filtering units 51. A part of the light-shielding portions 52 are provided in the corner area MK1.

Optionally, the light-filtering units 51 in the light-filtering layer 50 may be opposite to the light-emitting layer in the display light-emitting layer 20.

Optionally, the light-shielding portion 52 may enclose an opening area in the first area A1, and the light-filtering unit 51 may be provided in the opening area.

Optionally, the light-filtering portions may selectively transmit or block light with specific wavelengths based on design requirements to achieve color display or enhance saturation of specific colors.

Optionally, the light-shielding portions 52 may prevent leakage or crosstalk of the light through a gap between the light-filtering units 51.

Optionally, extension shapes of the touch traces 42 are the same as extension shapes of the light-shielding portions 52 in the corner area MK1.

Optionally, orthographic projections of first segments 421 of the touch traces 42 in the first sub-area on the substrate 10 partially overlap with orthographic projections of the light-shielding portions 52 in the corner area MK1 on the substrate 10.

In these optional embodiments, the light-shielding portions 52 are provided in the corner area MK1, so that shielded shapes of various areas in the first sub-area are the same, improving display uniformity in the first sub-area, reducing a possibility of display abnormality, and improving the display effect.

As shown in FIG. 6, in some optional embodiments, the display panel 100 includes a mask area MK, and the mask area MK includes the corner area MK1. The touch trace 42 includes a first segment 421 and a second segment 422 connected to each other, and along a direction from the first area A1 to the second area A2, the first segment 421 is provided in the first sub-area that does not overlap with the corner area MK1, and the second segment is provided in the second sub-area that overlaps with the corner area MK1.

The touch trace 42 includes the first segment 421 and the second segment 422 connected to each other, and along the direction from the first area A1 to the second area A2, the first segment 421 is provided in the first sub-area that does not overlap with the corner area MK1, and the second segment 422 is provided in the second sub-area that overlaps with the corner area MK1.

The touch trace 42 includes the first segment 421 and the second segment 422 connected to each other, and an example is given in which the first area A1 is a rectangle in shape, the first sub-area is a rectangular ring in shape, and the second sub-area is a rectangular ring in shape. The first segment 421 may be provided in a long side area or a short side area of the first sub-area and extend along the extension direction of the long side area or the short side area of the first sub-area. The second segment 422 may be provided at a location where the long side area and the short side area of the second sub-area are connected to each other. In an example, the first segment 421 extends in a straight line, and the second segment 422 extends in a straight line; a transition segment is provided between the first segment 421 and the second segment 422 and extends from the first sub-area to the second sub-area, one end of the transition segment located in the first sub-area is connected to the first segment 421, and the other end of the transition segment located in the second sub-area is connected to the second segment 422.

In these optional embodiments, through the above arrangements, the first segment 421 and the second segment 422 of the touch trace 42 are provided in the first sub-area and the second sub-area, respectively, which is beneficial to reduce a difficulty of manufacturing the touch traces 42 while increasing a space for providing the touch traces 42. FIG. 12 is yet another partial schematic structural view of P in FIG. 2.

As shown in FIG. 12, in some optional embodiments, the touch trace 42 includes a connection segment 424 and a plurality of third segments 423, and adjacent two of the third segments 423 are connected by the connection segment 424. An orthographic projection of the connection segment 424 on the substrate 10 extends along edges of orthographic projections of the first sub-support structures 211 on the substrate 10.

In an example, the orthographic projections of the first sub-support structures 211 on the substrate 10 are rectangles in shape, and the orthographic projections of the connection segments 424 on the substrate 10 may be zigzag lines in shape and extend along an edge of the first sub-support structure 211. Alternatively, the orthographic projections of the first sub-support structures 211 on the substrate 10 are circles in shape, and the orthographic projections of the connection segments 424 on the substrate 10 are arcs in shape and extends along the edge of the first sub-support structure 211.

Alternatively, the orthographic projections of the connection segments 424 on the substrate 10 may overlap with the orthographic projections of the second sub-support structures 212 on the substrate 10. Of course, the orthographic projections of the connection segments 424 on the substrate 10 may not overlap with the orthographic projections of the second sub-support structures 212 on the substrate 10.

In these optional embodiments, providing the third segments 423 and the connection segments 424 may improve wiring flexibility of the touch traces 42, increase a space utilization rate of the second area A2, and reduce an overall area of the second area A2.

As shown in FIG. 12, in some optional embodiments, the second area A2 further includes a binding area A21 in which the orthographic projection of the connection segment 424 on the substrate 10 is located at a side of the orthographic projections of the first sub-support structures 211 on the substrate 10 away from the first area A1.

Optionally, the bonding area A21 is provided between the control chip IC and the first area A1.

It may be understood that, in the binding area A21, the plurality of touch traces 42 are provided side by side, and the orthographic projection of the connection segment 424 on the substrate 10 is located at a side of the orthographic projections of the first sub-support structures 211 on the substrate 10 away from the first area A1, so that one or several touch traces 42 on a side of the touch trace 42 away from the first area A1 all have the connection segments 424, and have the same extension shapes as the connection segments 424 of the touch traces 42 adjacent to first sub-support structures 211 to improve the space utilization rate of the plurality of touch traces 42 in the binding area A21.

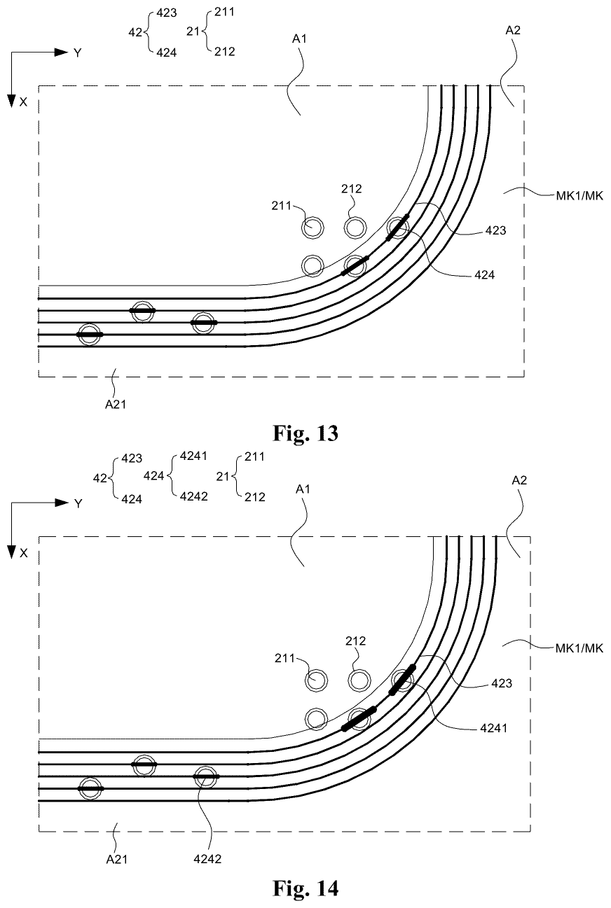

Thick solid lines of the third segment 423, thick solid lines of the connection segment 424, thick solid lines of a first sub-connection segment 4241, and thick solid lines of a second sub-connection segment 4242 in FIG. 13 and FIG. 14 are for embodying differences in radial dimensions of the third segment 423, the connection segment 424, the first sub-connection segment 4241, and the second sub-connection segment 4242.

FIG. 13 is yet another partial schematic structural view of P in FIG. 2.

As shown in FIG. 13, in some optional embodiments, the touch trace 42 includes a connection segment 424 and a plurality of third segments 423, and adjacent two of the third segments 423 are connected by the connection segment 424; and an orthographic projection of the connection segment 424 on the substrate 10 at least partially overlaps with orthographic projections of the first sub-support structures 211 on the substrate 10, and a radial dimension of the connection segment 424 is greater than a radial dimension of the third segment 423.

In these optional embodiments, the radial dimension of the connection segment 424 is greater than the radial dimension of the third segment 423, which is beneficial to increase a contact area between the connection segment 424 and a film layer under the connection segment 424, and reduce a possibility that the connection segments 424 are damaged or even broken due to an unevenness of the film layer under the connection segment 424. In addition, an overall radial dimension of the touch traces 42 may be reduced as much as possible, space occupied by the touch traces 42 in the second area A2 may be reduced, and an overall dimension of the second area A2 may be reduced.

FIG. 14 is yet another partial schematic structural view of P in FIG. 2.

As shown in FIG. 14, in some optional embodiments, the display panel 100 includes the mask area MK including the corner area MK1. The second area A2 further includes a binding area A21, the connection segment 424 includes a first sub-connection segment 4241 provided in the corner area MK1 and a second sub-connection segment 4242 provided in the binding area A21, and a radial dimension of the first sub-connection segment 4241 is greater than a radial dimension of the second sub-connection segment 4242.

It may be understood that the touch traces 42 around a periphery of the first area A1 all extend through the binding area A21 and are electrically connected to the control chip IC located on a side of the binding area away from the first area A1, and the radial dimension of the first sub-connection segment 4241 is different from the radial dimension of the second sub-connection segment 4242, which is beneficial to reduce space occupied by the second sub-connection segments 4242 in the binding area A21 and may improve the manufacturing yield of the touch traces 42.

Optionally, the radial dimension of the second sub-connection segment 4242 is greater than the radial dimension of the third segment 423.

FIG. 15 is yet another partial schematic structural view of P in FIG. 2.

As shown in FIG. 15, in some optional embodiments, the first sub-support structures 211 are provided in the first area Al.

Optionally, the first sub-support structures 211 are provided only in the first area A1 and are not provided in the second area A2, reducing an effect of the first sub-support structures 211 on the touch traces 42 in the second area A2.

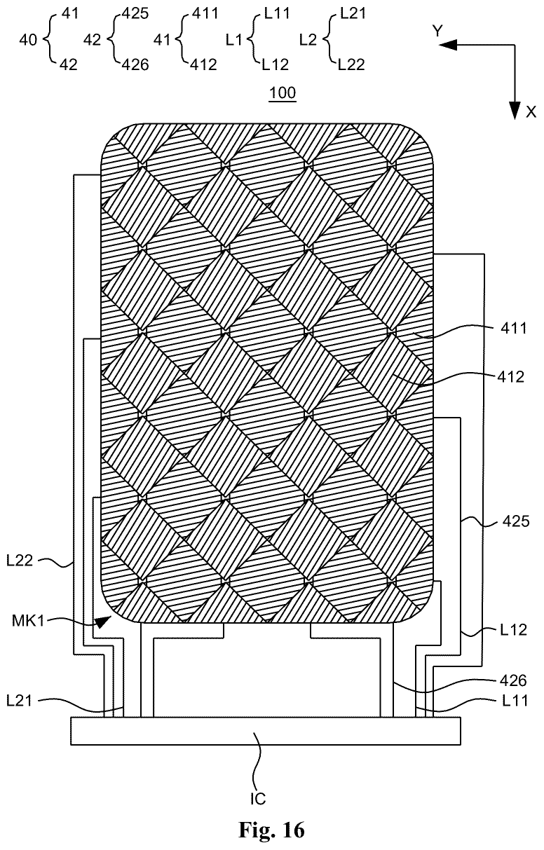

Thin solid lines and thick solid lines of the first touch traces 425 in FIG. 16 to FIG. 18 are for embodying first touch traces 425 with different radial dimensions in a plurality of first touch traces 425.

FIG. 16 is a schematic structural view of yet another display panel according to some embodiments of the present application.

As shown in FIG. 2 and FIG. 16, in some optional embodiments, the touch traces 42 include N first touch traces, the touch electrodes 41 include first touch electrodes 411, and the first touch traces 425 are electrically connected to the first touch electrodes; the display panel 100 further includes a control chip IC located in the second area A2 at a side of the first area Al along the first direction X. The first touch traces 425 extend along at least one of the sides of the first area Al opposite in the second direction Y and are connected to the control chip IC, and the first direction X intersects the second direction Y. The first touch traces 425 include a first set of touch traces L1 and a second set of touch traces L2, the first set of touch traces L1 includes the 1st first touch trace L11 to the M-th first touch trace L12, the second set of touch traces L2 includes the (M+1)-th first touch trace L21 to the N-th first touch trace L22, and N>2. The 1st first touch trace L11 is electrically connected to the first touch electrode 411 close to the control chip IC, and orthographic projections of at least a part of the first touch traces in the first set of touch traces L1 on the substrate 10 do not overlap with at least the orthographic projections of the first sub-support structures 211 on the substrate 10.

Optionally, a plurality of first touch electrodes 411 are arranged in a column along the first direction X and in a row along the second direction Y. The 1st first touch trace L11 is electrically connected to the first touch electrode 411 close to the control chip IC, in which the first 1st touch trace L11 may be understood as the first touch trace that is electrically connected to one row of first touch electrodes 411 in a plurality of rows of first touch electrodes 411 that is adjacent to the control chip IC along the first direction X.

Optionally, the first set of touch traces L1 and the second set of touch traces L2 may be controlled in a time-shared manner.

Optionally, projections of all of the first touch traces in the first set of touch traces L1 on the substrate 10 do not overlap with the orthographic projections of the first sub-support structures 211 on the substrate. Alternatively, projections of a part of the plurality of first touch traces in the first set of touch traces L1 on the substrate 10 do not overlap with the orthographic projections of the first sub-support structures 211 on the substrate.

Optionally, projections of all of the first touch traces in the second set of touch traces L2 on the substrate 10 do not overlap with the orthographic projections of the first sub-support structures 211 on the substrate. Alternatively, projections of a part of the plurality of first touch traces in the second set of touch traces L2 on the substrate 10 do not overlap with the orthographic projections of the first sub-support structures 211 on the substrate.

In these optional embodiments, it is beneficial to reduce the effect of the first sub-support structures 211 on the first touch traces and improve the manufacturing yield.

As shown in FIG. 2, in some optional embodiments, the first set of touch traces L1 and the second set of touch traces L2 are provided on two sides of the first area A1 along the second direction Y, respectively. Alternatively, as shown in FIG. 15, odd-numbered first touch traces and even-numbered first touch traces in the first set of touch traces L1 are provided on two sides of the first area A1 along the second direction Y, respectively; and odd-numbered first touch traces and even-numbered first touch traces in the second set of touch traces L2 are provided on two sides of the first area A1 along the second direction Y, respectively.

In some embodiments, as shown in FIG. 2, the first set of touch traces L1 and the second set of touch traces L2 are provided on two sides of the first area A1 along the second direction Y, respectively, which is beneficial to reduce mutual interference between the two sets of touch traces 42 and make the wiring more concise and orderly. In addition, since the first set of touch traces L1 is closer to the control chip IC than the second set of touch traces L2, extension lengths of the first touch traces in the two sets of touch traces 42 may be set in sequence on a regular basis to improve design accuracy of the first touch traces.

In some embodiments, as shown in FIG. 15, the odd-numbered first touch traces in the first set of touch traces L1 and the odd-numbered first touch traces in the second set of touch traces L2 may be located on the same side of the first area A1 along the first direction X; the even-numbered first touch traces in the first set of touch traces L1 and the even-numbered first touch traces in the second set of touch traces L2 may be located on the same side of the first area A1 along the first direction X. In some other embodiments, the odd-numbered first touch traces in the first set of touch traces L1 and the even-numbered first touch traces in the second set of touch traces L2 may be located on the same side of the first area A1 along the first direction X; the even-numbered first touch traces in the first set of touch traces L1 and the odd-numbered first touch traces in the second set of touch traces L2 may be located on the same side of the first area A1 along the first direction X. In the above embodiment, different wiring schemes may be used for the first touch traces, improving wiring flexibility of the first touch traces and improving design flexibility of the touch traces.

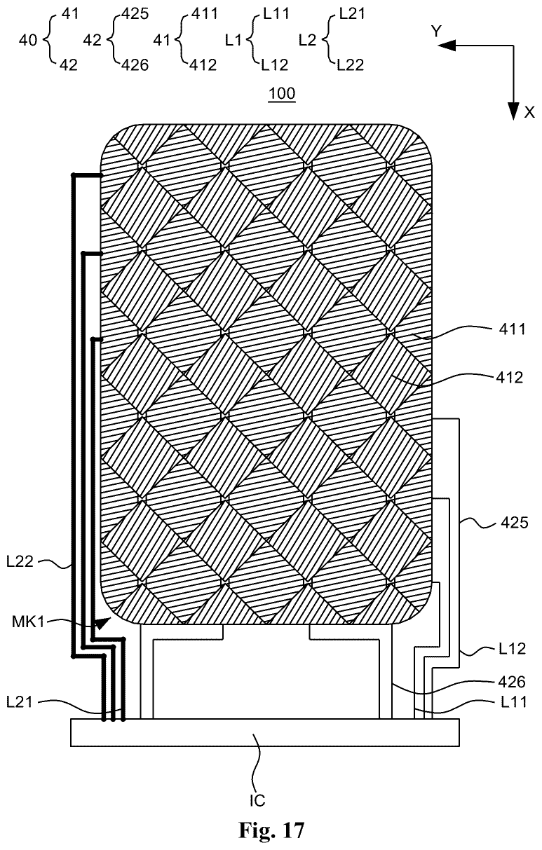

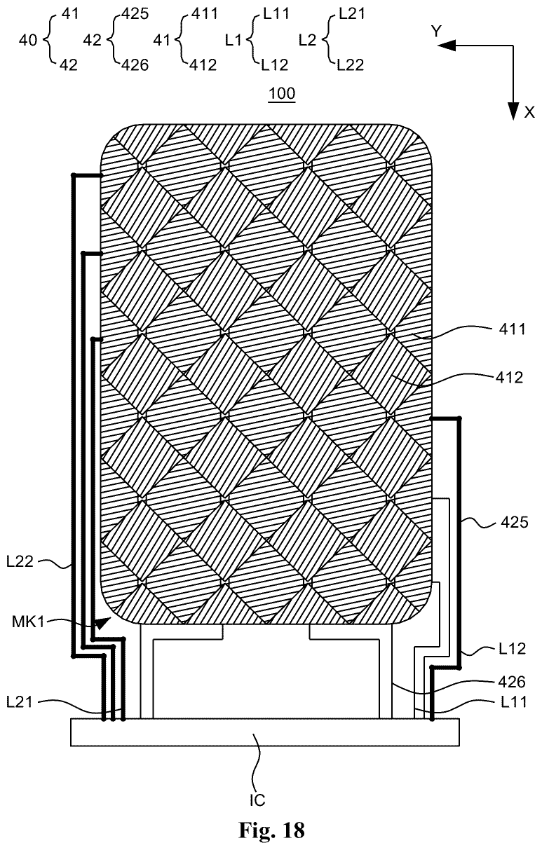

FIG. 17 is a schematic structural view of yet another display panel according to some embodiments of the present application. FIG. 18 is a schematic structural view of yet another display panel according to some embodiments of the present application.

As shown in FIG. 17 and FIG. 18, in some optional embodiments, radial dimensions of at least a part of the first touch traces in the first set of touch traces L1 are less than radial dimensions of the second set of touch traces L2.

In some embodiments, as shown in FIG. 17, a radial dimension of the first touch trace in the first set of touch traces L1 is less than a radial dimension of the first touch trace in the second set of touch traces L2. In some other embodiments, as shown in FIG. 17, radial dimensions of first touch traces in the first set of touch traces L1 close to the second set of touch traces L2 are the same as the radial dimensions of the first touch traces in the second set of touch traces L2, and radial dimensions of first touch traces in the first touch trace away from the second set of touch traces L2 are less than the radial dimensions of the first touch traces in the second set of touch traces L2.

It can be understood that a distance between the first set of touch traces L1 and the control chip IC is less than a distance between the second set of touch traces L2 and the control chip IC, so that extension lengths of the first set of touch traces L1 are less than extension lengths of the second set of touch traces L2; under a condition that radial dimensions of the first set of touch traces L1 are equal to radial dimensions of the second set of touch traces L2, resistance of the first set of touch traces L1 is less than resistance of the second set of touch traces L2. In the embodiments of the present application, the radial dimensions of the first set of touch traces L1 are less than the radial dimensions of the second set of touch traces L2, so that cross-sectional areas of the second set of touch traces L2 are increased, the resistance of the second set of touch traces L2 is reduced, and the resistance of the first set of touch traces L1 is equal to the resistance of the second set of touch traces L2, reducing an effect of the resistance on the touch signal, and improving touch performance.

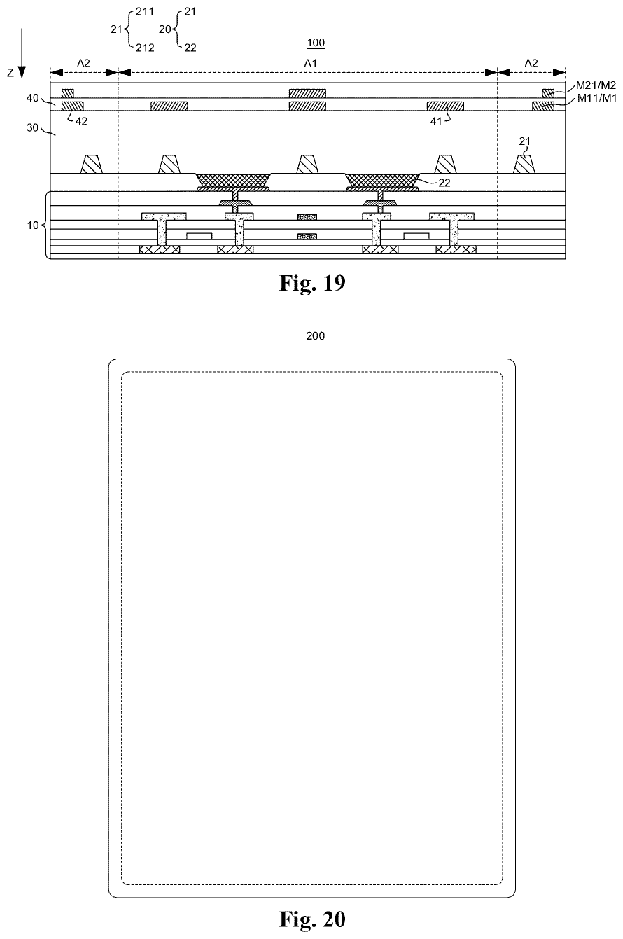

FIG. 19 is a sectional schematic structural view of yet another display panel according to some embodiments of the present application.

As shown in FIG. 19, in some optional embodiments, the touch layer 40 includes a first conductive layer M1 and a second conductive layer M2 that are provided in sequence along a direction away from the substrate 10, and the touch traces 42 include first conductive portions M11 provided in the first conductive layer M1 and second conductive portions M21 provided in the second conductive layer M2. Orthographic projections of the first conductive portions M11 on the substrate 10 and orthographic projections of the second conductive portions M21 on the substrate 10 at least partially overlap. Radial dimensions of at least a part of the first conductive portions M11 are greater than radial dimensions of the second conductive portions M21.

Optionally, the first touch trace 425 includes the first conductive layer M1 and the second conductive layer M2.

Optionally, the second touch trace 426 includes the first conductive layer M1 and the second conductive layer M2.

In some embodiments, orthographic projections of the first conductive portions M11 on the substrate 10 at least partially overlap with orthographic projections of the second conductive portions M21 on the substrate.

In combination with the above embodiments, by “the radial dimensions of at least a part of the first conductive portions M11 being greater than the radial dimensions of the second conductive portions M21”, it may be meant that radial dimensions of the first conductive portions M11 of the third segments 423 may be the same as or different from, for example greater than, the radial dimensions of the second conductive portions M21 of the third segments 423. The radial dimension of the first conductive portion M11 of the connection segment 424 is greater than the radial dimension of the second conductive portion M21 of the connection segment 424, and the orthographic projection of the first conductive portion M11 on the substrate 10 overlaps with the orthographic projection of the first sub-support structure 211 on the substrate.

In these optional embodiments, the radial dimension of the first conductive portion M11 is different from the radial dimension of the second conductive portion M21, and since the first conductive portion M11 is located between the support structure 21 and the second conductive portion M21, the radial dimension of the first conductive portion M11 is increased to reduce a risk of cracking or even disconnection of the first conductive portion M11 due to an unevenness of lower film layers, and the radial dimension of the second conductive portion M21 is small, which beneficial to reduce space occupied by the second conductive portions M21 in the second area A2 and an overall dimension of the second area.

FIG. 20 is a schematic structural view of a display apparatus according to some embodiments of the present application.

As shown in FIG. 20, in a second aspect, the embodiments of the present application further provides a display apparatus 200 including any one of the above display panels.

Since the display apparatus according to the embodiments of the present application includes the touch panel according to any one of the above embodiments, the display apparatus according to the embodiment of the present application has the beneficial effects of the touch panel according to any one of the above embodiments, which is not repeated herein.

Although the present application has been described with reference to the preferred embodiments, various modifications can be made thereto and components thereof can be replaced with their equivalents without departing from the scope of the present application. In particular, various technical features described in various embodiments can be combined in any manner as long as there is no structural conflict. The present application is not limited to the specific embodiments described herein, and includes all technical solutions that fall within the scope of the claims.

1. A display panel comprising a first area and a second area provided around the first area, and the display panel further comprising:
a substrate;
a display light-emitting layer provided on the substrate, wherein the display light-emitting layer comprises a plurality of support structures each comprising a first sub-support structure and a second sub-support structure, and a dimension of the first sub-support structure along a thickness direction of the display panel is greater than a dimension of the second sub-support structure along the thickness direction of the display panel; and
a touch layer comprising touch electrodes and a plurality of touch traces, wherein the touch traces are electrically connected to the touch electrodes, the touch electrodes are located in the first area, and the touch traces are located in the second area;
wherein orthographic projections of at least a part of the plurality of touch traces on the substrate do not overlap with orthographic projections of the first sub-support structures on the substrate.

2. The display panel according to claim 1, wherein at least a part of the first sub-support structures and/or the second sub-support structures are provided in the second area.

3. The display panel according to claim 2, wherein the second sub-support structure is provided around a periphery of the first sub-support structure, and the second sub-support structure is connected to a sidewall of the first sub-support structure.

4. The display panel according to claim 1, wherein the second area comprises a first sub-area provided around the first area and a second sub-area located at a side of the first sub-area away from the first area; and
the display panel comprises a mask area covering the first area and the first sub-area, the mask area comprises a corner area covering corners of the first area and the first sub-area, and the first sub-support structures and/or the second sub-support structures are provided in the corner area.

5. The display panel according to claim 2, wherein orthographic projections of the first sub-support structures and/or the second sub-support structures on the substrate do not overlap with orthographic projections of the touch trace on the substrate.

6. The display panel according to claim 4, wherein the display panel further comprises a control chip located in the second area on a side of the first area along a first direction, and the corner area is a corner located in the first area close to the control chip along the first direction.

7. The display panel according to claim 4, wherein the touch layer further comprises virtual touch traces insulated from the touch traces, and the virtual touch traces are provided in the corner area.

8. The display panel according to claim 7, wherein the touch traces comprise a first touch trace and a second touch trace, the touch electrodes comprise a first touch electrode and a second touch electrode insulated from each other, the first touch trace is electrically connected to the first touch electrode, the second touch trace is electrically connected to the second touch electrode, and the touch layer further comprises shielding lines each located between the first touch trace and the second touch trace; and
at least a part of the virtual touch traces are electrically connected to the shielding lines.

9. The display panel according to claim 4, wherein the display panel further comprises a light-filtering layer located on a side of the touch layer away from the substrate, the light-filtering layer comprises light-filtering units and light-shielding portions, and the light-shielding portion is located between two light-filtering units; and
a part of the light-shielding portions are provided in the corner area.

10. The display panel according to claim 1, wherein the second area comprises a first sub-area provided around the first area and a second sub-area located at a side of the first sub-area away from the first area, and the display panel comprises a mask area comprising a corner area; and
the touch trace comprises a first segment and a second segment connected to each other, and along a direction from the first area to the second area, the first segment is provided in the first sub-area that does not overlap with the corner area, and the second segment is provided in the second sub-area that overlaps with the corner area.

11. The display panel according to claim 1, wherein the touch trace comprises a connection segment and a plurality of third segments, and adjacent two of the third segments are connected by the connection segment; and
an orthographic projection of the connection segment on the substrate extends along edges of orthographic projections of the first sub-support structures on the substrate.

12. The display panel according to claim 11, wherein the second area further comprises a binding area in which the orthographic projection of the connection segment on the substrate is located at a side of the orthographic projections of the first sub-support structures on the substrate away from the first area.

13. The display panel according to claim 1, wherein the touch trace comprises a connection segment and a plurality of third segments, and adjacent two of the third segments are connected by the connection segment; and an orthographic projection of the connection segment on the substrate at least partially overlaps with orthographic projections of the first sub-support structures on the substrate, and a radial dimension of the connection segment is greater than a radial dimension of the third segment.

14. The display panel according to claim 13, wherein the display panel comprises a mask area comprising a corner area; and
the second area further comprises a binding area, the connection segment comprises a first sub-connection segment provided in the corner area and a second sub-connection segment provided in the binding area, and a radial dimension of the first sub-connection segment is greater than a radial dimension of the second sub-connection segment.

15. The display panel according to claim 1, wherein the first sub-support structures are provided in the first area.

16. The display panel according to claim 1, wherein the touch traces comprise N first touch traces, the touch electrodes comprise first touch electrodes, the first touch traces are electrically connected to the first touch electrodes, and the display panel further comprises a control chip located in the second area on a side of the first area along a first direction;
the first touch traces extend along at least one of opposite sides of the first area in a second direction and are connected to the control chip, and the first direction intersects the second direction;
the first touch traces comprise a first set of touch traces and a second set of touch traces, the first set of touch traces comprises a 1st first touch trace to an M-th first touch trace, the second set of touch traces comprises an (M+1)-th first touch trace to an N-th first touch trace, and N≥2; and
the 1st first touch trace is electrically connected to the first touch electrode close to the control chip, and orthographic projections of at least a part of the first touch traces in the first set of touch traces on the substrate do not overlap with at least the orthographic projections of the first sub-support structures on the substrate.

17. The display panel according to claim 16, wherein the first set of touch traces and the second set of touch traces are provided on two sides of the first area along the second direction, respectively; or
odd-numbered first touch traces and even-numbered first touch traces in the first set of touch traces are provided on two sides of the first area along the second direction, respectively; and odd-numbered first touch traces and even-numbered first touch traces in the second set of touch traces are provided on two sides of the first area along the second direction, respectively.

18. The display panel according to claim 17, wherein radial dimensions of at least a part of the first touch traces in the first set of touch traces are less than radial dimensions of the second set of touch traces.

19. The display panel according to claim 1, wherein the touch layer comprises a first conductive layer and a second conductive layer that are provided in sequence along a direction away from the substrate, the touch traces comprise first conductive portions provided in the first conductive layer and second conductive portions provided in the second conductive layer, and orthographic projections of the first conductive portions on the substrate at least partially overlaps with orthographic projections of the second conductive portions on the substrate; and
radial dimensions of at least a part of the first conductive portions are greater than radial dimensions of the second conductive portions.

20. A display apparatus comprising a display panel, and the display panel further comprising:
a substrate;
a display light-emitting layer provided on the substrate, wherein the display light-emitting layer comprises a plurality of support structures each comprising a first sub-support structure and a second sub-support structure, and a dimension of the first sub-support structure along a thickness direction of the display panel is greater than a dimension of the second sub-support structure along the thickness direction of the display panel; and
a touch layer comprising touch electrodes and a plurality of touch traces, wherein the touch traces are electrically connected to the touch electrodes, the touch electrodes are located in the first area, and the touch traces are located in the second area;
wherein orthographic projections of at least a part of the plurality of touch traces on the substrate do not overlap with orthographic projections of the first sub-support structures on the substrate.
